(19) United States
(12) Patent Application Publication
(10) Pub. No.: US 2009/0035911 A1
(43) Pub. Date: Feb. 5, 2009

(54) METHOD FOR FORMING A SEMICONDUCTOR DEVICE HAVING ABRUPT ULTRA SHALLOW EPI-TIP REGIONS

(76) Inventors: Willy Rachmady, Beaverton, OR (US); Steven Keating, Beaverton, OR (US); Bernhard Sell, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/830,155

(22) Filed: Jul. 30, 2007

(51) Int. Cl. H01L 21/336

(52) U.S. Cl. 438/300; 257/E21.409

(57) ABSTRACT

A method for forming a semiconductor device having abrupt ultra shallow epi-tip regions comprises forming a gate stack on a crystalline substrate, performing a first ion implantation process to amorphisize a first pair of regions of the substrate disposed adjacent to and on laterally opposite sides of the gate stack, forming a pair of spacers on the substrate disposed on laterally opposite sides of the gate stack, performing a second ion implantation process to amorphisize a second pair of regions of the substrate that are disposed on laterally opposite sides of the gate stack and adjacent to the spacers, applying a selective wet etch chemistry to remove the amorphisized first and second pair of regions and form a pair of cavities on laterally opposite sides of the gate stack, and depositing a silicon alloy in the pair of cavities to form source and drain regions and source and drain epi-tip regions.

### BACKGROUND

Increased performance of circuit devices on a substrate (e.g., integrated circuit (IC) transistors, resistors, capacitors, etc. on a semiconductor substrate) is usually a major factor considered during design, manufacture, and operation of those devices. For example, during design and manufacture or forming of, metal oxide semiconductor (MOS) transistor semiconductor devices, such as those used in a complementary metal oxide semiconductor (CMOS), it is often desired to increase movement of electrons in N-type MOS device (NMOS) channel regions and to increase movement of positive charged holes in P-type MOS device (PMOS) channel regions.

One method of reducing the overall resistance of a MOS device is to dope the area between the source/drain regions and the channel region, known as the tip regions of a MOS device. For instance, a dopant may be implanted in the source/drain regions and an anneal may be carried out to diffuse the dopant towards the channel region.

Because an implant and diffusion method is used, the ability to control the dopant concentration and location is limited. Furthermore, the size of other parts of a MOS device, such as the thickness of its offset spacers, can also have a great impact on the location of the tip regions. All of this, in turn, affects the ability of the tip regions to maximize dopant concentration and come into close proximity of the channel region. Accordingly, improved methods or structures are needed to overcome the limitations of conventional tip regions.

### BRIEF DESCRIPTION OF THE DRAWINGS

FIG. 1A illustrates a conventional MOS device that includes source and drain implanted tip regions.

FIG. 1B illustrates a MOS device that includes source and drain epi-tip regions.

FIG. 1C illustrates how spacer thickness impacts the etching of epi-tip regions of a MOS device.

FIG. 1D is a graph illustrating the dependence of UC-to-UC distance on spacer thickness.

FIG. 2 is a method of forming source and drain epi-tip regions in accordance with an implementation of the invention.

FIGS. 3A to 31 illustrate structures that are formed when carrying out the method of FIG. 2.

### DETAILED DESCRIPTION

Described herein are systems and methods of forming abrupt ultra shallow tip regions in a metal-oxide-semiconductor (MOS) device. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

By way of background, a conventional metal oxide semiconductor (MOS) transistor includes source and drain “tip regions” that are designed to decrease the overall resistance of the transistor while improving short channel effects. These tip regions are portions of the substrate where a dopant such as boron or arsenic is implanted using an implant and diffusion technique. The source tip region is formed in the area between the source region and the channel region. Likewise, the drain tip region is formed in the area between the drain region and the channel region. The tip regions minimally underdiffuse the gate dielectric layer of the transistor.

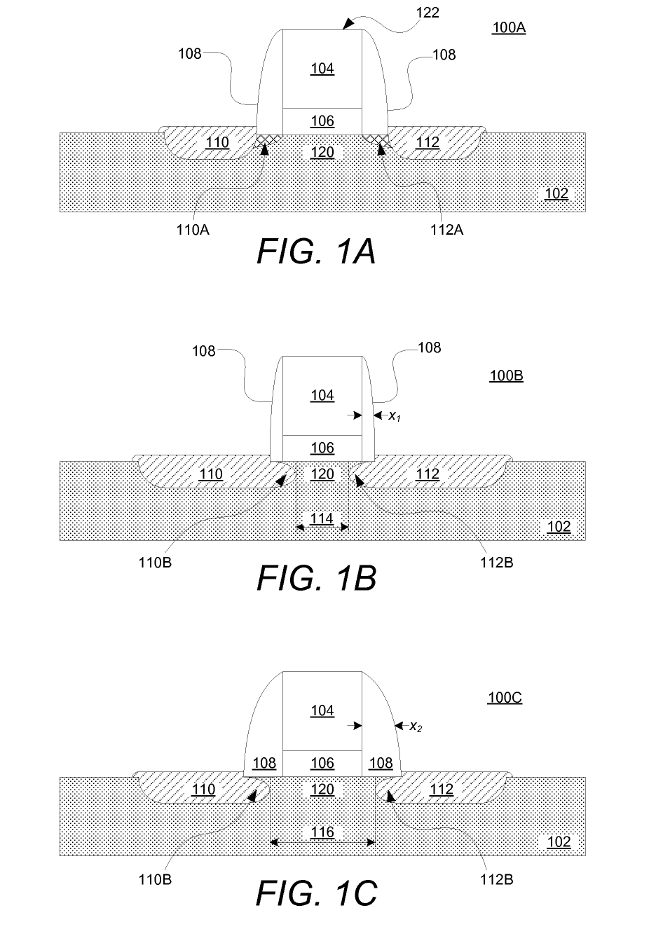

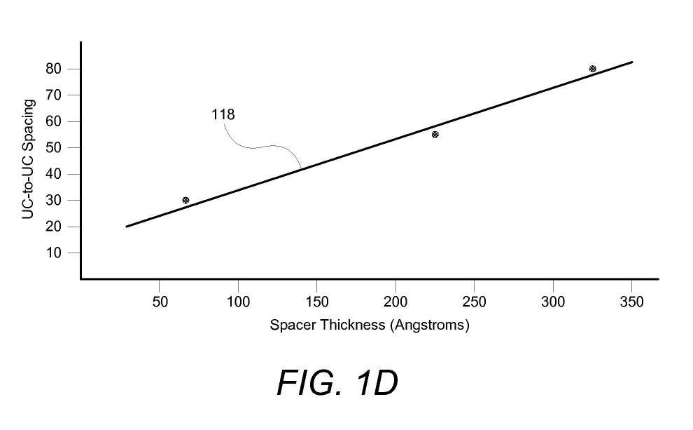

FIG. 1A illustrates a conventional MOS transistor 100A formed on a substrate 102. The source region 110 and the drain region 112 are typically formed by either implanting dopants such as boron into the substrate or by etching the substrate and then epitaxially depositing a silicon or silicon germanium material. A gate stack 122 is formed atop a channel region 120 of the transistor 100A. The gate stack 122 includes a gate dielectric layer 106 and a gate electrode 104. A pair of spacers 108 are formed adjacent to the gate stack 122.

As is known in the art, the spacers 108 generally create a distance of about 10 to 20 nanometers (nm) between the edges of the gate dielectric layer 106 and the edges of each of the source and drain regions 110/112. It is within this space that a source tip region 110A and a drain tip region 112A are formed using implantation and diffusion processes. The implanted tip regions 110A/112A overlap the spacers 108 and may overlap or underdiffuse the gate dielectric layer 106 by a distance of less than 10 nm.

One implant and diffusion process used to fabricate the source tip region 110A and the drain tip region 112A generally begins by implanting a dopant into the source region 110 and the drain region 112. Dopants that may be used include, but are not limited to, boron, arsenic, germanium, phosphorous, indium, or antimony. The dopant dosage may range from 1×10¹⁴ to 1×10¹⁶ atoms/cm³. The transistor 100A is then annealed to cause the dopant to diffuse towards the channel region 120. Angled ion implantation techniques may also be used to further implant dopants into those areas between the gate dielectric layer 106 and the source/drain regions 110/112. The end result is the formation of the implanted tip regions 110A/112A.

Unfortunately, as will be recognized by those of skill in the art, the shape of the implanted tip regions 110A/112A, the distance the dopants penetrate below the spacers 108, and the concentration gradient of the implanted tip regions 110A/112A are all dependent on the diffusion properties of the dopant in the substrate material. For instance, the concentration of the implanted tip regions will be high proximate to the source/drain region 110/112 and low proximate to the channel region 120. Although highly desired, it is nearly impossible to make the dopant concentration proximate to the channel region 120 very high without driving the dopant into the channel region 120. Furthermore, the source and drain regions 110/112 cannot be moved closer to the channel region 120 because the dopant may again be driven into the channel region 120. This limits how close the source and drain regions 110/112 can be formed to the channel region 120, thereby constraining how far the gate length may be scaled down.

FIG. 1B illustrates a MOS transistor 100B formed on a substrate 102 in accordance with implementations of the invention. Contrary to the prior art in which dopants are implanted and diffused under the spacers 108 to form implanted tip regions, implementations of the invention use an undercut etch to form voids beneath the spacers 108 that are epitaxially filled to form a source epi-tip region 110B and a drain epi-tip region 112B. The etch also removes portions of the substrate to form a source region 110 and a drain region 112. The source and drain epi-tip regions 110B/112B replace the less desirable implanted tip regions 110A/112A described in FIG. 1A.

The source/drain regions 110/112 and the source/drain epi-tip regions 110B/112B are formed by etching the substrate, which includes undercutting the spacers, and then epitaxially depositing a silicon or silicon germanium material. The source and drain epi-tip regions 110B/112B are therefore formed in the same process step as the source and drain regions 110/112, thereby reducing the overall number of process steps. The source and drain epi-tip regions 110B/112B also provide further advantages over the source/drain implanted tip regions 110A/112A. For instance, unlike implanted tip regions, the lattice structure of the source/drain epi-tip regions 110B/112B induces a strain in the channel region 120 that increases electron mobility and therefore decreases resistance in the channel.

Another advantage is that the interface between the source/drain epi-tip regions 110B/112B and the substrate material 102 that forms the channel region 120 is abrupt. On one side of the interface is the epitaxially deposited doped silicon material and on the other side of the interface is the substrate material that makes up the channel region 120. This structure enables the epitaxially-formed source/drain epi-tip regions 110B/112B to bring the heavily doped silicon material in very close proximity to the channel region 120. The dopants in the source/drain epi-tip regions 110B/112B remain substantially or completely within the epi-tip regions and do not tend to diffuse into the channel region 120.

Unfortunately, conventional undercut etching techniques result in the formation of a bulleted profile for the undercut region, as illustrated in FIG. 1B. In other words, more of the substrate material is etched a slight distance below the gate dielectric layer 106 than is etched directly adjacent to the gate dielectric layer 106. This causes the source epi-tip region 110B and the drain epi-tip region 112B to have a bulleted profile as well, thereby producing a less than optimal stain in the channel region 120. Furthermore, because there is a great deal of variance in conventional undercut etching techniques, there tends to be a lot of variance in the resulting source and drain epi-tip regions 110B/112B that are formed.

Another disadvantage to conventional methods of forming source and drain epi-tip regions 110B/112B concerns the effect that spacer thickness has on the undercut etch, as described in FIGS. 1B and 1 C. Starting with FIG. 1B, the MOS transistor 100B is shown having offset spacers 108 of a first thickness x₁. A substrate etch has been performed that undercuts the spacers 108 and a portion of the gate dielectric layer 106 to enable the formation of source and drain epi-tip regions 110B/112B. An undercut-to-undercut (UC-to-UC) distance 114 separates source epi-tip region 110B from drain epi-tip region 112B.

Moving to FIG. 1C, a MOS transistor 100C is shown with offset spacers 108 having a thickness x₂. Here, the thickness x₂ is much greater than the thickness x₁ of the spacers 108 in FIG. 1B. As a result, when the substrate etch is performed, the thicker spacers 108 push out the undercut etch and cause the source/drain epi-tip regions 110B/112B to be formed further away from the channel region 120 of the transistor 100C. The substrate etch therefore undercuts less of the surface area beneath the MOS transistor 100C. Accordingly, a UC-to-UC distance 116 for the MOS transistor 100C is much larger than the UC-to-UC distance 114 for the MOS transistor 100B. Unfortunately, altering the UC-to-UC distance in this manner yields large drive current variations for the MOS transistors.

FIG. 1D is a graph illustrating how spacer thickness affects the UC-to-UC distance in devices formed using known methods. The graph provides data, represented by line 118, showing that as spacer thickness increases, the UC-to-UC distance also increases, leading to large drive current variations. Typically, for every nanometer (nm) of spacer thickness increase, the UC-to-UC distance increases by around 2 nm. As such, forming source/drain epi-tip regions using conventional methods permits the thickness of the offset spacer to have a tremendous impact on the performance of the MOS device.

To address these issues described above, implementations of the invention provide methods of forming novel, self-aligned and epitaxially deposited source and drain epi-tip regions. The source and drain epi-tip regions of the invention place highly doped silicon material in close proximity to the channel region of a MOS transistor. And because the source and drain epi-tip regions are self-aligned, they are substantially less impacted by offset spacer thickness relative to conventional processes.

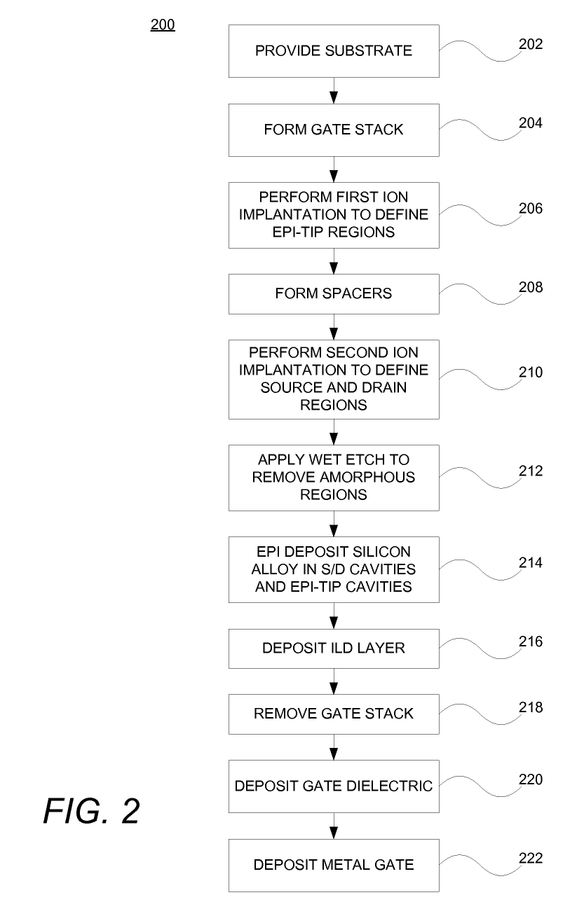

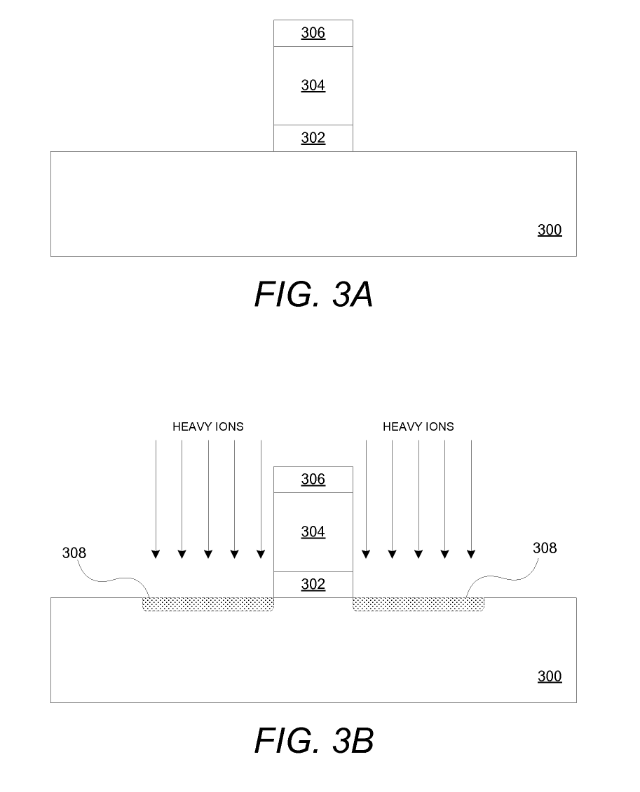

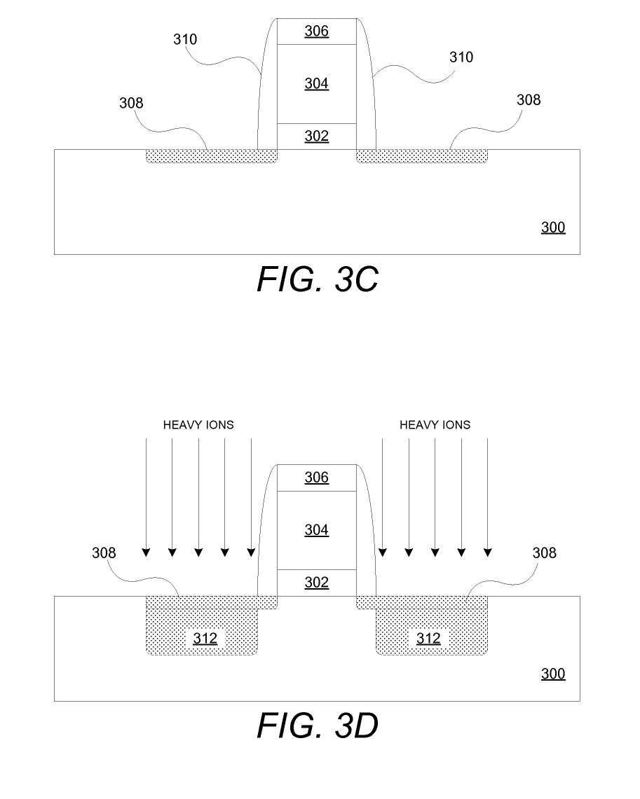

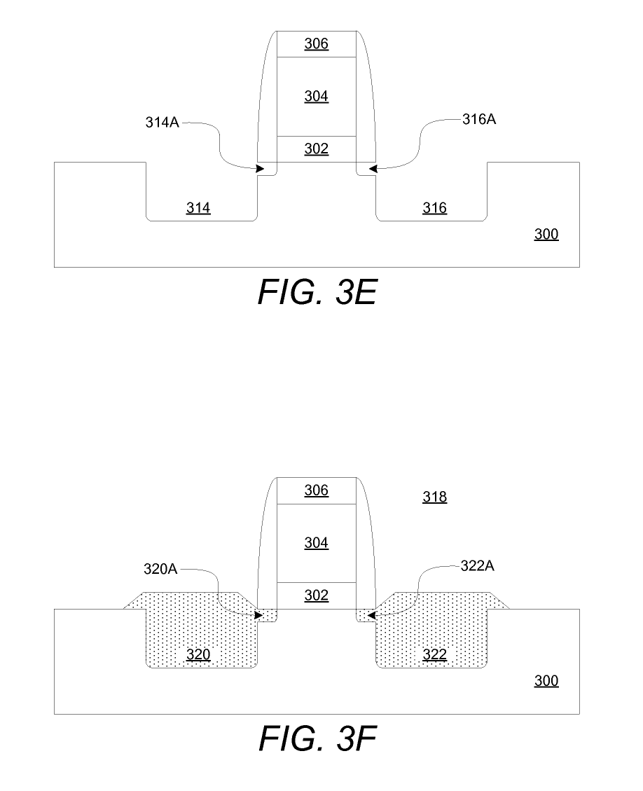

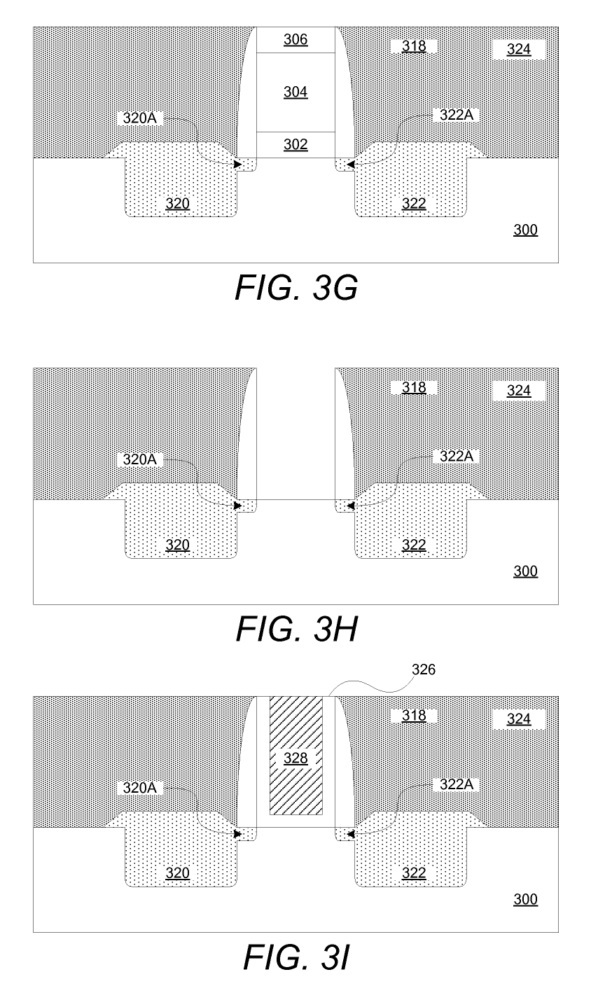

FIG. 2 is a method 200 of fabricating a MOS transistor with self-aligned epitaxial source and drain epi-tip regions. FIGS. 3A through 31 illustrate structures that are formed when the method 200 of FIG. 2 is carried out.

The method 200 begins with a semiconductor substrate upon which a MOS device, such as a MOS transistor, may be formed (process 202 of FIG. 2). The semiconductor substrate is a crystalline substrate that may be formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

A gate stack is formed on the semiconductor substrate (204). In some implementations of the invention, the gate stack may be formed by depositing and then patterning a gate dielectric layer and a gate electrode layer. For instance, in one implementation, a gate dielectric layer may be blanket deposited onto the semiconductor substrate using conventional deposition processes such as chemical vapor deposition (CVD), atomic layer deposition (ALD), spin-on deposition (SOD), or physical vapor deposition (PVD). Alternate deposition techniques may be used as well, for instance, the gate dielectric layer may be thermally grown. Next, a gate electrode material may be deposited on the gate dielectric layer using similar deposition techniques such as ALD, CVD, or PVD. In some implementations, the gate electrode material is polysilicon or a metal layer. In some implementations, the gate electrode material is a sacrificial material that can later be removed for a replacement metal gate process. A conventional patterning process may then be carried out to etch away portions of the gate electrode layer and the gate dielectric layer to form the gate stack.

The gate dielectric material may be formed from materials such as silicon dioxide or high-k dielectric materials. Examples of high-k gate dielectric materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, the high-k gate dielectric layer may be between around 5 Angstroms (Å) to around 50 Å thick. In further embodiments, additional processing may be performed on the high-k gate dielectric layer, such as an annealing process to improve the quality of the high-k material.

FIG. 3A illustrates a substrate 300 upon which a gate stack is formed. In the implementation described here, the gate stack may include a high-k gate dielectric layer 302 and a sacrificial gate electrode 304. In other implementations, the gate stack may include a silicon dioxide gate dielectric layer and a polysilicon gate electrode. The gate stack may also include a gate hard mask layer 306 that provides certain benefits or uses during processing, such as protecting the gate electrode 304 from subsequent ion implantation processes. In implementations of the invention, this hard mask layer 306 may be formed using materials conventionally used as hard masks, such as such as a conventional dielectric materials.

After the gate stack is formed, a first ion implantation process is carried out to dope and amorphisize portions of the substrate adjacent to the gate stack (206). This first ion implantation process defines the epi-tip regions of the MOS transistor being formed. In accordance with implementations of the invention, a relatively high dosage of heavy ions is implanted using a relatively low implant energy. Heavy ions that may be used in implementations of the invention include, but are not limited to, silicon (Si), arsenic (As), germanium (Ge), phosphorous (P), tin (Sn), antimony (Sb), and tellurium (Te). The dopant used in the ion implantation process is chosen based on its ability to amorphisize the silicon substrate, in other words, the dopant is capable of breaking up the crystalline structure of the silicon substrate and creating a region of amorphous silicon. In further implementations, the specific dopant selected for the ion implantation process may vary based on the substrate material and the etchant used in a subsequent etching process. Since most substrates contain a large silicon, germanium, or indium antimonide component, dopants that amorphisize silicon, germanium, or indium antimonide may be chosen.

In implementations of the invention, the heavy ions are implanted to a relatively shallow depth that falls between 1 nm and 50 nm, depending on the desired depth of the amorphization to form the epi-tip regions. An appropriate ion implantation energy is chosen to implant the heavy ions to the desired depth. In some implementations, this ion implantation energy may fall between around 1 kilo-electron volt (keV) and around 15 keV. In addition, the implant dosage for the heavy ions may fall between around 1×10¹⁴ and around 1×10¹⁷ atoms/cm³. The implant dosage and implantation energy will generally vary based on which heavy ion is chosen and the desired depth of the amorphization. For instance, if the heavy ion is silicon, in one implementation the dosage used may be around 6×10¹⁵atoms/cm³ and the implantation energy may be around 2 keV, which yields an amorphization depth of around 3 nm.

In some implementations of the invention, the ion implantation substantially occurs in a vertical direction (i.e., a direction perpendicular to substrate). In other implementations, at least a portion of the ion implantation process may occur in an angled direction to implant ions below the gate stack.

As mentioned above, the gate electrode may comprise a polysilicon or a metal layer. In implementations where the gate electrode consists of polysilicon, the polysilicon may be pre-doped with dopants appropriate for use in either an NMOS transistor or a PMOS transistor, including but not limited to As, P, or boron (B). In implementations where the gate electrode consists of a metal layer, a dielectric gate hard mask layer may be formed on the gate stack to prevent doping of the metal gate electrode, as previously shown in FIG. 3A.

FIG. 3B illustrates the substrate 300 after the first ion implantation process. As shown, the first ion implantation process creates two amorphous regions 308 adjacent to the gate dielectric layer 302 that may later be removed using an appropriate wet etchant. A portion of one of the amorphous regions 308 defines a self-aligned source epi-tip region for the MOS transistor being formed. A portion of the other amorphous region 308 defines a self-aligned drain epi-tip region for the MOS transistor. As described above, the size of the amorphous regions 308, including their depth, may vary based on the requirements of the MOS transistor being formed.

Next, spacers are formed on either side of the gate stack using a low temperature process (208). A low temperature process is used to maintain the amorphous state of the doped regions. The spacers may be formed using materials appropriate for low temperature processes, including but not limited to silicon oxide or silicon nitride. A deposition process such as sputtering, ALD, or CVD may be used to deposit the spacer material at a temperature below 540° C. and an etching process may follow to pattern the spacers. The width of the spacers may be chosen based on design requirements for the MOS transistor being formed. In accordance with implementations of the invention, because the source and drain epi-tip regions are self-aligned, the width of the spacers is not subject to design constraints imposed by the formation of the source and drain epi-tip regions. FIG. 3C illustrates the substrate 300 with spacers 310 formed on either side of the gate electrode layer 304 and the gate dielectric layer 302.

After the spacers are formed on the substrate, a second ion implantation process is carried out to amorphisize regions of the substrate where a source region and a drain region will be formed (210). This second ion implantation process defines the source and drain regions of the MOS transistor being formed. This second ion implantation process also uses a relatively high dosage of heavy ions, but unlike the first ion implantation process, the second ion implantation process uses a relatively high implant energy. Again, heavy ions that may be used in implementations of the invention include, but are not limited to, Si, As, Ge, P, Sn, Sb, and Te.

In this second ion implantation process, the heavy ions are implanted to a depth that falls between 10 nm and 100 nm or more, depending on the desired depth of the source and drain regions being formed. A relatively higher ion implantation energy is chosen to implant the heavy ions to the depth necessary for the source and drain regions. In some implementations, this ion implantation energy may range between around 10 keV and around 60 keV. In addition, the implant dosage for the heavy ions may fall between around 1×10¹⁴ and around 1×10¹⁷ atoms/cm³. The implant dosage and implantation energy will generally vary based on which heavy ion is chosen.

FIG. 3D illustrates the substrate 300 after the second ion implantation process. As shown, the second ion implantation process creates two amorphous regions 312 proximate to the spacers 310 that may be removed using an appropriate wet etchant. One of the amorphous regions 312 defines a source region for the MOS transistor being formed. The other amorphous region 312 defines a drain region for the MOS transistor. As described above, the size of the amorphous regions 312, including their depth, may vary based on the requirements of the MOS transistor being formed.

After the second set of amorphous regions are formed, a wet etch process is carried out to selectively etch and remove all of the amorphous regions on the substrate (212). This includes the amorphous regions formed during the first ion implantation process as well as the amorphous regions formed during the second ion implantation process. The wet etch process uses an etchant recipe designed to selectively remove amorphous silicon while removing little or no crystalline silicon. In accordance with one implementation of the invention, the wet etch chemistry may include nitric acid, hydrofluoric acid, and carboxylic acid diluents such as acetic acid or citric acid. The end result of the wet etch process is the formation of cavities in which source/drain regions and source/drain epi-tip regions may be grown or deposited.

FIG. 3E illustrates the substrate 300 after the wet etch process has been carried out. As shown, a source region cavity 314 and a drain region cavity 316 are formed by removing the amorphous regions 312. Furthermore, a source epi-tip cavity 314A and a drain epi-tip cavity 316A are formed by removing the amorphous regions 308. The thickness of the spacer 310 has minimal impact on the etching of the source epi-tip cavity 314A and the drain epi-tip cavity 316A. As shown, the source and drain epi-tip cavities 314A and 316A do not have the bulleted profile that occurs in conventional processing.

Optionally, in some implementations of the invention, a second wet etch process may be applied to clean and further etch the source region cavity 314, the source epi-tip cavity 314A, the drain region cavity 316, and the drain epi-tip cavity 316A. Conventional wet etch chemistries known in the art for cleaning silicon and oxide material may be used. For instance, wet etch chemistries capable of removing silicon along its crystallographic planes may be used. The optional second wet etch serves at least two objectives. First, it removes contaminants such as carbon, fluorine, chlorofluorocarbons, and oxides such as silicon oxide to provide a clean surface upon which subsequent processes may be carried out. Second, the wet etch removes a thin portion of the substrate along the <111> and <001> crystallographic planes to provide a smooth surface upon which a high quality epitaxial deposition may occur. The thin portion of the substrate that is etched away may be up to 5 nm thick and may also remove residual contaminants.

The remainder of the process for forming the MOS transistor is similar to conventional MOS processing techniques. For example, after the etching process, the source and drain region cavities, as well as the source and drain epi-tip cavities, may be filled with a silicon alloy using a selective epitaxial deposition process (214). This epitaxial deposition therefore forms the source and drain regions and the source and drain epi-tip regions in one step. In some implementations, the silicon alloy may be in-situ doped silicon germanium, in-situ doped silicon carbide, or in-situ doped silicon. In alternate implementations, other silicon alloys may be used. For instance, alternate silicon alloy materials that may be used include, but are not limited to, nickel silicide, titanium silicide, cobalt silicide, and possibly may be doped with one or more of boron and/or aluminum. In some implementations, a CVD process may be used for the deposition.

In implementations, the silicon alloy material that is deposited in the source and drain region cavities has a lattice spacing that is different than the lattice spacing of the substrate material. The difference in lattice spacing induces a tensile or compressive stress in the channel region of the MOS transistor that is accentuated by depositing the silicon alloy in the source and drain epi-tip regions. As is known to those of skill in the art, deciding whether to induce a tensile stress or a compressive stress will depend on whether an NMOS or a PMOS transistor is being formed.

In accordance with implementations of the invention, for an NMOS transistor, the source and drain region cavities may be filled with carbon doped silicon. The carbon doped silicon may be epitaxially and selectively deposited. In further implementations, the carbon doped silicon may be further doped in situ with phosphorous. In some implementations of the invention, the carbon concentration may range from 0.5 atomic % to 3.0 atomic %, the phosphorous concentration may range from 5×10¹⁹/cm³ to 5×10²¹/cm³ and the thickness of the carbon doped silicon may range from 400 Å to 1200Å. The carbon and phosphorous doped silicon may be denoted as (C,P)_{y}Si_{(1-y)}.

In some implementations, the deposition of the highly doped (C,P)_{y}Si_{(1-y)}source and drain regions may be carried out in a low pressure chemical vapor deposition (LPCVD) reactor using multiple cycles of a deposition and etch sequence based on silane (SiH₄), PH₃, CH₃SiH₃, and chlorine (Cl₂) chemistries. The reactor temperature may fall between 500° C. and 625° C. and the reactor pressure may be below 20 Pa. To achieve selectivity, epitaxy, and high dopant concentrations, the process parameters described in the following paragraphs may be used.

In some implementations, for the deposition phase, the co-reactants may include SiH₄ at a flow rate between 100 and 400 standard cubic centimeters per minute (SCCM), CH₃SiH₃ at a flow rate between 25 and 150 SCCM, PH₃ at a flow rate between 1 and 25 SCCM, and H₂ at a flow rate between 500 and 4000 SCCM. Each cycle of the deposition phase may last up to 4 minutes.

The deposition phase may be followed by a first purge phase. The first purge may include nitrogen at a flow rate between 500 SCCM and 2 standard liters per minute (SLM) and N₂Cl₂ at a flow rate between 5 and 50 SCCM. Each cycle of the first purge phase may last up to 10 seconds.

In some implementations, an etch phase may follow the purge phase. For the etch phase, the co-reactants may include Cl₂ at a flow rate between 5 and 25 SCCM. Each cycle of the etch phase may last up to 30 seconds.

The etch phase may be followed by a second purge phase. This second purge may include nitrogen at a flow rate between 50 SCCM and 2 SLM and N₂Cl₂ at a flow rate between 5 and 35 SCCM. Each cycle of the second purge phase may last up to 10 seconds.

In some implementations, the second purge phase may be followed by a third purge phase. The third purge may include hydrogen (H₂) at a flow rate between 5 and 25 SLM. Each cycle of the third purge phase may last up to 2 minutes.

In accordance with implementations of the invention, for a PMOS transistor, the source and drain region cavities may be filled with silicon germanium. The silicon germanium may be epitaxially deposited. In some implementations of the invention, the germanium concentration may range from 10 atomic % to 50 atomic %. In further implementations, the silicon germanium may be further doped in situ with boron. The boron concentration may range from 2×10¹⁹/cm³ to 7×10²⁰/cm³. The thickness of the silicon germanium may range from 40 Å to 1500 Å.

Deposition of the doped silicon germanium may be carried out in a CVD reactor, an LPCVD reactor, or an ultra high vacuum CVD (UHVCVD). The reactor temperature may fall between 600° C. and 800° C. and the reactor pressure may fall between 1 and 760 Torr. The carrier gas may consist of hydrogen or helium at a flow rate that ranges between 10 and 50 SLM.

In some implementations, the deposition may be carried out using a silicon source precursor gas such as dichlorosilane (DCS or SiH₂Cl₂), silane (SiH₄), or disilane (Si₂H₆). For instance, DCS may be used at a flow rate that ranges between 15 and 100 SCCM. The deposition may also use a germanium source precursor gas such as GeH₄ that is diluted in H₂ (e.g., the GeH₄ may be diluted at 1-5%). For instance, the diluted GeH₄ may be used at a 1% concentration and at a flow rate that ranges between 50 and 300 SCCM. For an in situ doping of boron, diluted B₂H₆ may be used (e.g., the B₂H₆ may be diluted in H₂ at 1-5%). For instance, the diluted B₂H₆ may be used at a 3% concentration and at a flow rate that ranges between 10 and 100 SCCM. In some implementations, an etching agent may be added to increase the selectivity of the deposition. For instance, HCl or Cl₂ may be added at a flow rate that ranges between 50 and 300 SCCM.

FIG. 3F illustrates a MOS transistor 318 in which the source region cavity 314 has been filled with a silicon alloy to form a source region 320 and the drain region cavity 316 has been filled with a silicon alloy to form a drain region 322. The epi-tip cavities 314A/316A have also been filled in the same process step to form a source epi-tip region 320A and a drain epi-tip region 322A. As shown in FIG. 3F, unlike conventional source and drain tip regions that are formed through implant and diffusion techniques and therefore have no clear boundary between the tip regions and the channel region, the self-aligned, source and drain epi-tip regions of the invention have an abrupt boundary. In other words, the interface between the source/drain epi-tip regions and the channel region is clear and well-defined. On one side of the interface is the epitaxially deposited, highly-doped silicon material and on the other side of the interface is the substrate material that makes up the channel region. The dopants in the source/drain epi-tip regions remain substantially or completely within the epi-tip regions and do not tend to diffuse into the channel region, thereby enabling the source and drain epi-tip regions of the invention to bring the heavily doped silicon material in very close proximity to the channel region relative to conventional techniques. As will be appreciated by those of skill in the art, this in turn enables the gate length to scale down without shortening the channel region.

Forming the source and drain epi-tip regions in relatively close proximity to the channel region also imparts a larger hydrostatic stress on the channel. This stress increases the strain within the channel, thereby increasing mobility in the channel and increasing drive current. This stress can be further amplified by increasing the doping of the source and drain epi-tip regions, which is easily controlled during the epitaxial deposition of the silicon alloy. This is an improvement over conventional diffusion processes where the tip regions generally do not induce a strain on the channel region.

As will be appreciated by those of skill in the art, the MOS transistor may undergo further MOS processing, such as replacement gate oxide processes, replacement metal gate processes, annealing, or salicidation processes, that may further modify the transistor 318 and/or provide the necessary electrical interconnections. For instance, after the epitaxial deposition of the source/drain regions and the source/drain epi-tip regions, an interlayer dielectric (ILD) may be deposited and planarized over the transistor (216). The ILD may be formed using materials known for the applicability in dielectric layers for integrated circuit structures, such as low-k dielectric materials. Such dielectric materials include, but are not limited to, oxides such as silicon dioxide (SiO₂) and carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. FIG. 3G illustrates an ILD layer 324 that has been deposited over the MOS transistor 318.

Next, in implementations of the invention in which a replacement metal gate process is used, the gate stack (i.e., the high-k gate dielectric layer 302, the sacrificial gate electrode 304, and the hard mask layer 306) may be removed using an etching process (218). Methods for removing these layers are well known in the art. In alternate implementations, only the sacrificial gate 304 is removed. FIG. 3H illustrates the trench opening that is formed when the gate stack is etched away.

If the gate dielectric layer is removed, a new gate dielectric layer may be deposited into the trench opening (220). The high-k dielectric materials described above may be used here, such as hafnium oxide. The same deposition processes may also be used. Replacement of the gate dielectric layer may be used to address any damage that may have occurred to the original gate dielectric layer during application of the dry and wet etch processes. A metal gate electrode layer may then be deposited over the gate dielectric layer (222). Conventional metal deposition processes may be used to form the metal gate electrode layer, such as CVD, ALD, PVD, electroless plating, or electroplating. FIG. 31 illustrates a high-k gate dielectric layer 326 and a metal gate electrode 328 that have been deposited into the trench opening.

The metal gate electrode layer may consist of a P-type workfunction metal or an N-type workfunction metal, depending on whether the transistor is to be a PMOS or an NMOS transistor. In some implementations, a PMOS transistor is being formed and materials that may be used to form a P-type workfunction metal layer include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. Alternately, in some implementations an NMOS transistor is being formed and materials that may be used to form an N-type workfunction metal layer include, but are not limited to, hafnium, zirconium, titanium, tantalum, aluminum, and their alloys, e.g., metal carbides that include these elements, i.e., hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV. In some implementations, two or more metal gate electrode layers may be deposited. For instance, a workfunction metal may be deposited followed by a metal gate electrode fill metal such as aluminum metal.

Accordingly, self-aligned source and drain epi-tip regions have been disclosed that reduce the overall resistance of the MOS transistor and increase channel strain due to increased source/drain doped silicon volume (e.g., boron-doped silicon germanium volume or phosphorous and carbon-doped silicon volume) combined with reduced channel region silicon volume. The source and drain epi-tip regions do not have a bulleted profile, form an abrupt boundary between the channel region and the source and drain regions, and have a doping concentration that is more easily controlled, yielding a more optimized source-drain profile. Furthermore, implementations of the invention enable the source and drain epi-tip regions to be etched without being substantially impacted by the spacer thickness. This self-aligned process therefore increases performance while minimizing process variation.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
forming a gate stack on a crystalline substrate;
performing a first ion implantation process to amorphisize a first pair of regions of the substrate, wherein the first pair of regions are disposed adjacent to and on laterally opposite sides of the gate stack;
forming a pair of spacers on the substrate disposed on laterally opposite sides of the gate stack atop the amorphisized first pair of regions;
performing a second ion implantation process to amorphisize a second pair of regions of the substrate, wherein the second pair of regions are disposed on laterally opposite sides of the gate stack and adjacent to the spacers;
applying a selective wet etch chemistry that removes the amorphisized first and second pair of regions to form a pair of cavities on laterally opposite sides of the gate stack; and
depositing a silicon alloy in the pair of cavities to form a source region, a drain region, a source epi-tip region, and a drain epi-tip region.

2. The method of claim 1, wherein the first ion implantation process implants at least one heavy ion to amorphisize the substrate.

3. The method of claim 2, wherein the heavy ion is selected from the group consisting of silicon, arsenic, germanium, and phosphorous.

4. The method of claim 3, wherein the first ion implantation process uses an ion implantation energy between around 1 keV and around 15 keV.

5. The method of claim 3, wherein the first ion implantation process implants the heavy ion to a depth between 1 nm and 50 nm.

6. The method of claim 3, wherein the first ion implantation process uses a heavy ion dosage between around 1×10¹⁴ and around 1×10¹⁷ atoms/cm³.

7. The method of claim 1, wherein the second ion implantation process implants at least one heavy ion to amorphisize the substrate.

8. The method of claim 7, wherein the heavy ion is selected from the group consisting of silicon, arsenic, germanium, phosphorous, tin, antimony, and tellurium.

9. The method of claim 8, wherein the second ion implantation process uses an ion implantation energy between around 10 keV and around 60 keV.

10. The method of claim 8, wherein the second ion implantation process implants the heavy ion to a depth between 10 nm and 100 nm.

11. The method of claim 8, wherein the second ion implantation process uses a heavy ion dosage between around 1×10¹⁴ and around 1×10¹⁷ atoms/cm³.

12. The method of claim 1, wherein the forming of the pair of spacers comprises depositing and etching a layer comprising silicon nitride or silicon oxide at a temperature below 540° C.

13. The method of claim 1, wherein the wet etch chemistry comprises nitric acid, hydrofluoric acid, and a carboxylic acid diluent, wherein the carboxylic acid diluent comprises acetic acid or citric acid.

14. The method of claim 1, wherein the depositing of the silicon alloy comprises epitaxially depositing carbon doped silicon.

15. The method of claim 1, wherein the depositing of the silicon alloy comprises epitaxially depositing silicon doped with carbon and phosphorous.

16. The method of claim 1, wherein the depositing of the silicon alloy comprises epitaxially depositing silicon germanium doped with boron.

17. The method of claim 1, wherein the gate stack comprises:
a high-k gate dielectric layer;
a sacrificial layer formed on the high-k gate dielectric layer; and
a hard mask layer formed on the sacrificial layer.

18. The method of claim 17, further comprising:
depositing an ILD layer after the depositing of the silicon alloy;
removing the hard mask layer and the sacrificial layer to form a trench between the spacers; and
depositing a metal gate electrode into the trench.

19. The method of claim 17, further comprising:
depositing an ILD layer after the depositing of the silicon alloy;
removing the hard mask layer, the sacrificial layer, and the high-k gate dielectric layer to form a trench between the spacers;
depositing a new high-k gate dielectric layer into the trench; and
depositing a metal gate electrode into the trench.

20. The method of claim 1, wherein an interface between the source epi-tip region and the substrate is abrupt and wherein an interface between the drain epi-tip region and the substrate is abrupt.

21. The method of claim 1, wherein the first pair of regions define the source and drain epi-tip regions.

22. The method of claim 1, wherein the second pair of regions define the source and drain regions.

23. The method of claim 1, further comprising applying a second wet etch chemistry to the pair of cavities to remove portions of the substrate along the <111> and <001> crystallographic planes prior to the depositing of the silicon alloy.

24. A method comprising:
forming a gate stack on a crystalline substrate;
implanting heavy ions to amorphisize regions of the substrate that define a source epi-tip region and a drain epi-tip region;
forming a pair of spacers on laterally opposite sides of the gate stack;
implanting heavy ions to amorphisize regions of the substrate that define a source region and a drain region;
applying a selective wet etch chemistry to remove the amorphisized regions; and
depositing a silicon alloy in place of the removed amorphisized regions.

25. The method of claim 24, further comprising:
depositing an ILD layer after the depositing of the silicon alloy;
removing a hard mask layer and a sacrificial layer of the gate stack to form a trench between the spacers; and
depositing a metal gate electrode into the trench.

26. The method of claim 24, further comprising:
depositing an ILD layer after the depositing of the silicon alloy;
removing a hard mask layer, a sacrificial layer, and a high-k gate dielectric layer of the gate stack to form a trench between the spacers;
depositing a new high-k gate dielectric layer into the trench; and
depositing a metal gate electrode into the trench.

27. The method of claim 24, wherein the heavy ions are selected from the group consisting of silicon, arsenic, germanium, phosphorous, tin, antimony, and tellurium.

28. The method of claim 24, wherein the spacers are formed at a temperature below 540° C.

29. The method of claim 24, wherein the wet etch chemistry comprises nitric acid, hydrofluoric acid, and a carboxylic acid diluent, wherein the carboxylic acid diluent comprises acetic acid or citric acid.

30. The method of claim 24, wherein the silicon alloy is selected from the group consisting of carbon doped silicon, carbon and phosphorous doped silicon, silicon germanium, and boron doped silicon germanium.
